(19) United States
(12) Patent Application Publication
(10) Pub. No.: US 2011/0001467 A1
(43) Pub. Date: Jan. 6, 2011

(54) METHOD OPTIMIZING DRIVING VOLTAGE AND ELECTRONIC SYSTEM

(75) Inventors: Hyung Chan CHOI, Seoul (KR); Hee Joo CHOI, Hwasung-si (KR); Seung Man SHIN, Suwon-si (KR); Hui-Chung BYUN, Hwasung-si (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: SAMSUNG ELECTRONICS CO., LTD., Suwon-si (KP)

(21) Appl. No.: 12/791,241

(22) Filed: Jun. 1, 2010

(30) Foreign Application Priority Data
Jul. 6, 2009 (KR) 10-2009-0061168

(51) Int. Cl. G01R 19/00

(52) U.S. Cl. 324/76.11

(57) ABSTRACT

A method of optimizing a driving voltage of an electronic device includes; iteratively varying the level of a driving voltage provided to the electronic device and performing an operation of the electronic device with each iteration until the operation fails, and then selecting as an operating level for the driving voltage, a level of the driving voltage for an iteration just prior to an iteration in which the operation fails.

### CROSS-REFERENCE TO RELATED APPLICATIONS

A claim of priority under 35 U.S.C. §119 is made to Korean Patent Application No. 10-2009-0061168 filed Jul. 6, 2009, the subject matter of which is hereby incorporated by reference.

### BACKGROUND

The present inventive concept relates to a method of optimizing a driving voltage within an electronic device, and systems incorporating this type of method and related circuits.

Memory modules included in general computer systems are manufactured by many different companies. Since memory modules are manufactured using fabrication processes that vary by company, they include circuitry providing differing driving voltage, or driving voltage ranges. And this is true despite the efforts of various standards setting bodies like the Joint Electron Devices Engineering Council (JEDEC). In practical application, contemporary memory modules operates according to one or more driving voltages that exist within ranges that vary by manufacture and/or device type.

For example, many conventional memory modules operate according to a defined (and fixed) single driving voltage within a driving voltage range mandated by JEDEC standards. Thus, the level of the driving voltage is not a user changeable operation for most conventional memory modules. And in other circumstances, some conventional memory modules are designed to operate according to a driving voltage within a range lower than those mandated by JEDEC standards. However, such lower driving voltages are still fixed and unalterable by the user.

The provision of only a fixed driving voltage, regardless of level, in many emerging applications represents a real design limitation. Too high a fixed driving voltage leads to over-consumption of power within a memory module, while too low a fixed driving voltage risks inoperability.

### SUMMARY

Embodiments of the inventive concept provide a method of optimizing a driving voltage within an electronic device, as well as electronic systems capable of incorporating this type of method.

According to an aspect of the inventive concept, there is provided a method of optimizing a driving voltage of an electronic device, the method comprising; iteratively varying the level of a driving voltage provided to the electronic device and performing an operation of the electronic device with each iteration until the operation fails, and then selecting as an operating level for the driving voltage, a level of the driving voltage for an iteration just prior to an iteration in which the operation fails.

According to another aspect of the inventive concept, there is provided an electronic system comprising; an electronic device, and a control unit configured to iteratively vary the level of a driving voltage provided to the electronic device and perform an operation of the electronic device with each iteration until the operation fails, and then select as an operating level for the driving voltage, a level of the driving voltage for an iteration just prior to an iteration in which the operation fails.

### BRIEF DESCRIPTION OF THE DRAWINGS

Exemplary embodiments of the inventive concept will be more clearly understood from the following detailed description taken in conjunction with the accompanying drawings in which:

FIG. 1 is a schematic block diagram of an electronic system according to an embodiment to the inventive concept;

FIG. 2 is a schematic block diagram further illustrating the logic circuit of FIG. 1;

FIG. 3 is a flowchart summarizing a method of optimizing a driving voltage within an electronic system according to an embodiment of the inventive concept;

FIG. 4 is a timing diagram further illustrating the operation of the electronic system of FIG. 1;

FIG. 5 is a conceptual diagram further illustrating one possible mode of operation for the electronic system of FIG. 1; and

FIGS. 6A and 6B are graphs explaining an effect generated by the driving voltage optimization method performed by the electronic system of FIG. 1.

### DETAILED DESCRIPTION OF THE EMBODIMENTS

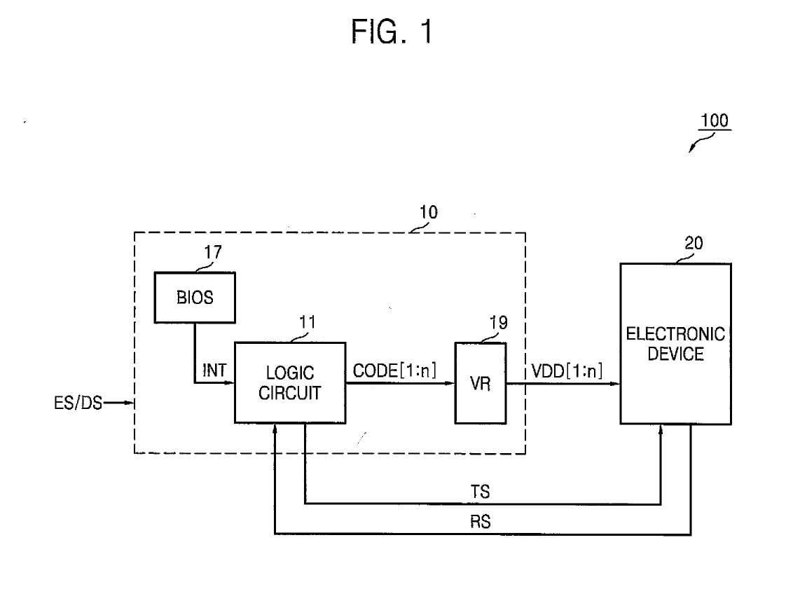

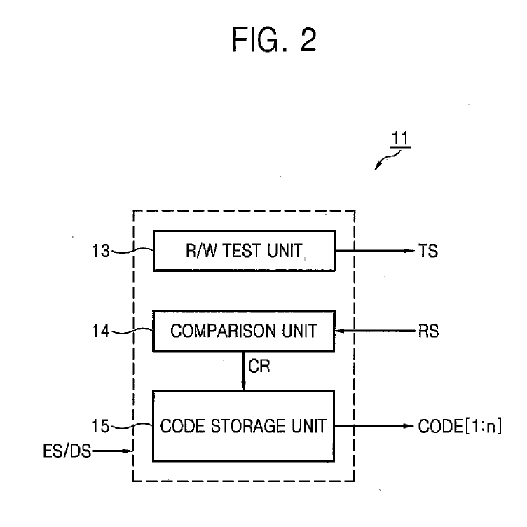

FIG. 1 is a schematic block diagram of an electronic system 100 according to an embodiment to the inventive concept, and FIG. 2 is a schematic block diagram further illustrating one possible embodiment of the logic circuit included within the electronic system 100.

For convenience of explanation, the embodiment illustrated by FIGS. 1 and 2 is assumed to be a computer system including a memory module. However, this is just one possible example of many different embodiments of the inventive concept. For example, the electronic system 100 may alternately be a card system, an image sensing system, etc.

Referring to FIG. 1, the electronic system 100 generally comprises a system control unit 10 and an electronic device 20. The system control unit 10 may be a control unit formed on a main board of the electronic system 100, namely, a computer system. The electronic device 20 may be a memory module connected to the main board, for example, a Single Inline Memory Module (SIMM) or a Double Inline Memory Module (DIMM).

The system control unit 10 may include a logic circuit 11, a BIOS 17, and a voltage regulator (VR) 19. The logic circuit 11 may operate according to an enable signal ES received from an external source, for example, a user. The logic circuit 11 may output a plurality of codes, for example, a plurality of driving voltage codes CODE[1;n] that allow the VR 19 to generate a plurality of driving voltages VDD[1;n], to the VR 19 in response to an enable signal ES.

In addition, the logic circuit 11 may output a test signal TS to the electronic device 20 that operates according to each of the driving voltages VDD[1;n] output from the VR 19, or test operation effectiveness of the electronic device 20 according to a response signal RS output by the electronic device 20 in response to the test signal TS.

Referring to FIG. 2, the logic circuit 11 may include a read/write (R/W) test unit 13, a comparison unit 14, and a code storage unit 15. The R/W test unit 13 may output the test signal TS to the electronic device 20 in response to the enable signal ES. The test signal TS may include a write test signal and a read test signal.

The comparison unit 14 may compare the test signal TS with the response signal RS output by the electronic device 20 of FIG. 1 in response to the test signal TS, and generate a comparison signal CR corresponding to a result of the comparison. The code storage unit 15 may store the driving voltage codes CODE[1;n] and sequentially output the driving voltage codes CODE[1;n] according to the comparison signal CR output from the comparison unit 14.

For example, the code storage unit 15 may be implemented in a look-up table. The code storage unit 15 may be included in the logic circuit 11 or may be installed as an independent memory in the system control unit 10 of FIG. 1. Referring back to FIG. 1, the logic circuit 11 may be CMOS circuitry within the computer system, but embodiments of the inventive concept are not limited thereto.

When the system control unit 10 is enabled, the BIOS 17 may output an initial information signal INT to the logic circuit 11. For example, the BIOS 17 may store the initial information signal INT including initial operation information of the system control unit 10 or initial operation information of the electronic device 20.

When the logic circuit 11 starts operating by the input of the enable signal ES from an external source to the system control unit 10, the BIOS 17 may output the initial information signal INT to the logic circuit 11. According to another embodiment, when power is applied from the external source to the system control unit 10, the BIOS 17 may output the initial information signal INT to the logic circuit 11.

The VR 19 may output the driving voltages VDD[1;n] corresponding to the driving voltage codes CODE[1;n], respectively, received from the logic circuit 11. For example, the VR 19 may be implemented into a digital analog converter (DAC) and may convert digital codes output from the logic circuit 11. That is, a plurality of driving voltage codes CODE[1;n] each including a binary code with at least one bit may be converted into analog signals, such as a plurality of analog driving voltages VDD[1;n].

The electronic device 20 may operate according to each of the driving voltages VDD[1;n] output from the system control unit 10, namely, from the VR 19, and may output the response signal RS in response to the test signal TS output from the logic circuit 11.

In the illustrated embodiment of FIGS. 1 and 2, the electronic device 20 is assumed to be a memory module such as a SIMM or a DIMM. However, the scope of the inventive concept is not limited thereto, and the electronic device 20 may be not only a SIMM or a DIMM, but also a storage device such as a Solid State Drive/Disk (SSD) or a flash memory.

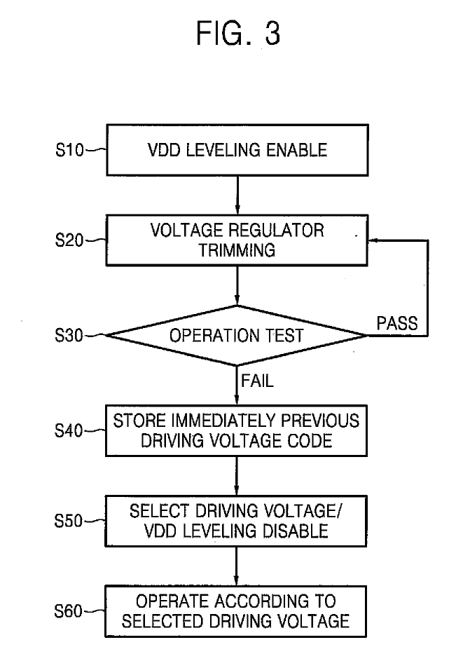

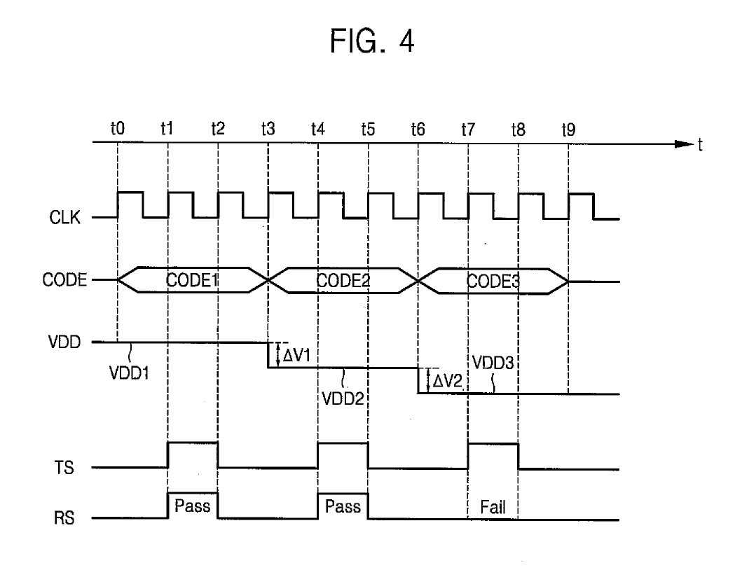

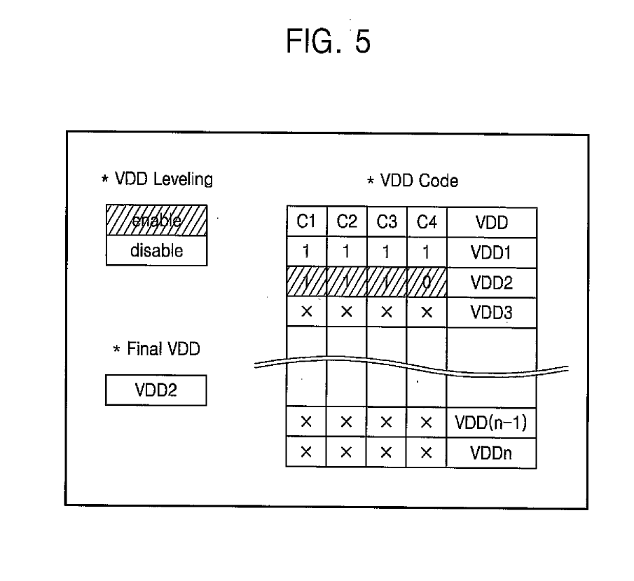

FIG. 3 is a flowchart summarizing one possible approach to a method of optimizing a driving voltage within the electronic system 100 illustrated of FIGS. 1 and 2. FIG. 4 is a related timing diagram for the operation of the electronic system 100, and FIG. 5 is a conceptual diagram further illustrating the operation of the electronic system 100.

Referring to FIGS. 1 through 4, when a user or a tester inputs the enable signal ES in order to optimize a driving voltage of the electronic device 20, the system control unit 10 may enter into a driving voltage optimization mode in response to the enable signal ES (S10).

When the system control unit 10 enters into the driving voltage optimization mode, the BIOS 17 of the system control unit 10 may output the initial information signal INT to the logic circuit 11.

Although the initial information signal INT may be a power-up sequence signal including the initial operation information of the system control unit 10 or the initial operation information of the electronic device 20, embodiments of the inventive concept are limited thereto.

The logic circuit 11 may sequentially output the driving voltage codes CODE[1;n] stored in the code storage unit 15 to the VR 19 according to the initial information signal INT output from the BIOS 17.

The VR 19 may convert the driving voltage codes CODE[1;n] output from the logic circuit 11 into the driving voltages VDD[1;n] and sequentially output each of the driving voltages VDD[1;n] to the electronic device 20 (S20). For example, at a time t0, the logic circuit 11 may output a first driving voltage code CODE1 (e.g., 1111), and an initial driving voltage code based on the initial information signal INT received from the BIOS 17, from among the driving voltage codes CODE[1;n] stored in the code storage unit 15 to the VR 19.

The VR 19 may output a first driving voltage VDD1 on the basis of the first driving voltage code CODE1 of 1111 received from the logic circuit 11. At a time t3, the logic circuit 11 may output a second driving voltage code CODE2 (e.g., 1110) to the VR 19, and the VR 19 may output a second driving voltage VDD2 on the basis of the second driving voltage code CODE2 of 1110.

At a time t6, the logic circuit 11 may output a third driving voltage code CODE3 (e.g., 1101) to the VR 19, and the VR 19 may output a third driving voltage VDD3 on the basis of the third driving voltage code CODE3 of 1101.

In the illustrated embodiment, the code storage unit 15 of the logic circuit 11 outputs sequentially-decreasing driving voltage codes to the VR 19, and thus the VR 19 outputs sequentially-decreasing driving voltages. However, other embodiments of the inventive concept are not limited thereto, and the code storage unit 15 of the logic circuit 11 may output sequentially-increasing driving voltage codes to the VR 19, and thus the VR 19 may output sequentially-increasing driving voltages.

The first, second, and third driving voltages VDD1, VDD2, and VDD3 may be sequentially output from the VR 19 so as not to be overlapped by each other, and provided to the electronic device 20 to operate the electronic device 20.

While the electronic device 20 is operating according to each of the driving voltages VDD[1;n], the logic circuit 11 may test the operation effectiveness of the electronic device 20 (S30). For example, while the electronic device 20 is operating according to the first driving voltage VDD1 generated from the first driving voltage code CODE1 during the time period t0 to t3, and the R/W test unit 13 of the logic circuit 11 may output the test signal TS to the electronic device 20.

The comparison unit 14 of the logic circuit 11 may test the operation effectiveness of the electronic device 20, according to the response signal RS output by the electronic device 20 in response to the test signal TS. In other words, during the time period t1 to t2, the R/W test unit 13 may output a write test signal TS to the electronic device 20. The write test signal TS may include a write command signal and a data signal (e.g., 1111) which is to be written. The electronic device 20 may write the data signal of 1111 in response to the write command signal.

During the time period t1 to t2, the R/W test unit 13 may output a read test signal to the electronic device 20. The read test signal may include a read command signal. The electronic device 20 may output as the response signal RS the data signal of 1111 stored therein in response to the read command signal.

The comparison unit 14 may compare the data signal of 1111 output to the electronic device 20 with the response signal RS output from the electronic device 20 and output the comparison signal CR corresponding to a result of the comparison. If the data signal of 1111 is the same as the response signal RS (if an operation of the electronic device 20 is passed), the comparison unit 14 may output the comparison signal CR for allowing the code storage unit 15 of the logic circuit 11 to output the next driving voltage code, for example, the second driving voltage code CODE2, to the VR 19.

According to another embodiment, the logic circuit 11 may optimize an operation environment of the electronic device 20 before outputting the test signal TS to the electronic device 20 and testing the operation effectiveness of the electronic device 20.

For example, when the electronic device 20 receives the first driving voltage VDD1, the electronic device 20 may perform leveling training for performing an optimized operation according to the first driving voltage VDD1. After this leveling training is completed, the logic circuit 11 may output the test signal TS to the electronic device 20 in order to test the operation effectiveness generated in an environment where the electronic device 20 operates with the first driving voltage VDD1.

According to another embodiment, the logic circuit 11 may output the test signal TS such as a Stress Memory Built-In Self Test (SMBIST) to the electronic device 20 in order to test the operation effectiveness of the electronic device 20. For example, the SMBIST may be a method of setting an artificially harsh test environment and testing operation effectiveness of the electronic device 20 corresponding to the artificially harsh test environment instead of simply testing a R/W operation of the electronic device 20. For example, the SMBIST may allow the logic circuit 11 to provide data having a worst data pattern within a short period of time to the electronic device 20 so that the electronic device 20 may perform a testing operation of reading/writing the data several tens to several hundreds of times.

When the second driving voltage code CODE2 is output from the code storage unit 15 to the VR 19 at time t3, the VR 19 may output the second driving voltage VDD2 according to the second driving voltage code CODE2 in S20.

The second driving voltage VDD2 may be obtained by reducing the first driving voltage VDD1 output from the VR 19 at the time t0 by a first voltage difference ΔV1. The second driving voltage VDD2 may be provided to the electronic device 20.

While the electronic device 20 is operating by the second driving voltage VDD2, the R/W test unit 13 of the logic circuit 11 may test the operation effectiveness of the electronic device 20 again (S30). For example, in the time period t4 to t5, the write test signal including the write command signal and the data signal of 1111 may be output from the R/W test unit 13 to the electronic device 20. The electronic device 20 may write the data signal of 1111 in response to the write command signal.

During the time period t4 to t5, the R/W test unit 13 may output the read test signal including the read command signal to the electronic device 20, and the electronic device 20 may output the data signal of 1111 stored therein in response to the read command signal to serve as the response signal RS.

The comparison unit 14 may compare the data signal of 1111 output to the electronic device 20 with the response signal RS output from the electronic device 20 and output the comparison signal CR corresponding to a result of the comparison.

If the data signal of 1111 is the same as the response signal RS (if the operation of the electronic device 20 is passed), the comparison unit 14 may output a comparison signal CR that allows the code storage unit 15 of the logic circuit 11 to output the next driving voltage code, for example, the third driving voltage code CODE3, to the VR 19.

When the third driving voltage code CODE3 is output from the code storage unit 15 to the VR 19 at the time t6, the VR 19 may output the third driving voltage VDD3 according to the third driving voltage code CODE3 in S20. The third driving voltage VDD3 output from the VR 19 may be obtained by reducing the second driving voltage VDD2 output from the VR 19 at the time t3 on the time axis t by a second voltage difference ΔV2. The third driving voltage VDD3 may be provided to the electronic device 20.

The first voltage difference ΔV1, namely, a difference between the first and second driving voltages VDD1 and VDD2, may be equal to the second voltage difference ΔV2, namely, a difference between the second and third driving voltages VDD2 and VDD3.

While the electronic device 20 is operating by the third driving voltage VDD3, the R/W test unit 13 of the logic circuit 11 may test the operation effectiveness of the electronic device 20 again (S30). For example, during the time period t7 to t8, the write test signal including the write command signal and the data signal of 1111 may be output from the R/W test unit 13 to the electronic device 20. The electronic device 20 may write the data signal of 1111 in response to the write command signal.

During the time period t7 to t8, the R/W test unit 13 may output the read test signal including the read command signal to the electronic device 20, and the electronic device 20 may output the response signal RS in response to the read command signal.

The comparison unit 14 may compare the data signal of 1111 output to the electronic device 20 with the response signal RS output from the electronic device 20 and output the comparison signal CR corresponding to a result of the comparison.

If the data signal of 1111 is not the same as the response signal RS (if the operation of the electronic device 20 is failed), the comparison unit 14 may output a comparison signal CR that allows the code storage unit 15 of the logic circuit 11 to output the immediately previous driving voltage code, for example, the second driving voltage code CODE2, to the VR 19.

The code storage unit 15 of the logic circuit 11 may store the second driving voltage code CODE2 according to the comparison signal CR output from the comparison unit 14 (S40). Then, the logic circuit 11 may pause the testing of the operation effectiveness of the electronic device 20.

The logic circuit 11 may display a test result as illustrated in FIG. 5 to users. The logic circuit 11 may display a test result to users after re-booting the system control unit 10. Users may select one driving voltage from the display test result and input a disable signal DS to prevent the system control unit 10 from performing a further driving voltage optimizing operation (S50).

For example, users may select either the first driving voltage code CODE1 or the second driving voltage code CODE2. Then, the users may input a signal for allowing the mode of the system control unit 10 to be changed from the driving voltage optimization mode into a normal operational mode, for example, the disable signal DS. When the disable signal DS is input to the system control unit 10 by a user, the system control unit 10 may output the second driving voltage VDD2 corresponding to a driving voltage code selected by the user, namely, the second driving voltage code CODE2, to the electronic device 20. The electronic device 20 may be operated by the second driving voltage VDD2 (S60).

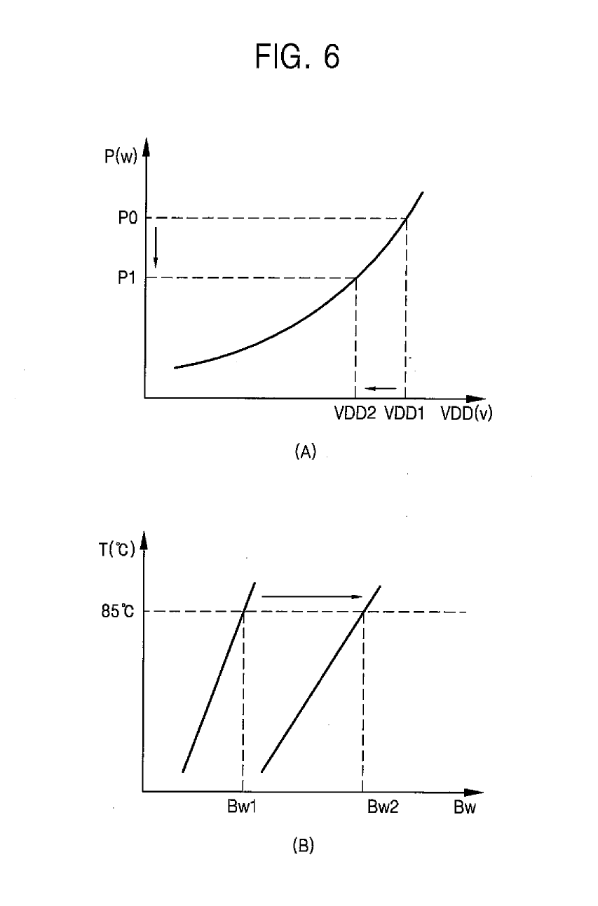

FIGS. 6A and 6B are graphs explaining an effect of driving voltage optimization performed by the electronic system 100. FIG. 6A is a graph showing power consumption in relation to driving voltage for the electronic device 20. As illustrated in FIG. 6A, when the electronic device 20 is operated by the initial driving voltage, for example, the first driving voltage VDD1, the electronic device 20 consumes a first power P0. On the other hand, when the electronic device 20 is operated by the second driving voltage VDD2 selected after the driving voltage optimization described above with reference to FIGS. 1 through 5 is performed, namely, the second driving voltage VDD2 having a lower voltage value than the initial driving voltage VDD1, the electronic device 20 consumes a second power P1 that is lower than the first power P0. In other words, when the optimization of the driving voltage of the electronic device 20 is performed, the power consumption by the electronic device 20 is reduced.

FIG. 6B is a graph showing operational bandwidth for the electronic device 20 at a certain temperature. The operational bandwidth of the electronic device 20 improves the performance of the electronic device 20. As illustrated in FIG. 6B, when the electronic device 20 is operated by the initial driving voltage, the electronic device 20 has a first bandwidth BW1. On the other hand, when the electronic device 20 is operated by the second driving voltage VDD2 selected after the driving voltage optimization described above with reference to FIGS. 1 through 5 is performed, the electronic device 20 has a second bandwidth BW2 that is greater than the first bandwidth BW1. In other words, when the optimization of the driving voltage of the electronic device 20 is performed, the operational bandwidth of the electronic device 20 is increased, and thus the performance of the electronic device 20 may be improved.

In a method of optimizing the driving voltage of an electronic device and an electronic system that performs the method, according to embodiments of the inventive concept, the driving voltage of the electronic device is optimized, so that power consumption by the electronic device operating in various environments can be reduced and users can determine the driving voltage of the electronic device. Thus, an efficient electronic system may be obtained.

While the inventive concept has been particularly shown and described with reference to exemplary embodiments thereof, it will be understood that various changes in form and details may be made therein without departing from the scope of the following claims.

What is claimed is:

1. A method of optimizing a driving voltage of an electronic device, the method comprising:
iteratively varying the level of a driving voltage provided to the electronic device and performing an operation of the electronic device with each iteration until the operation fails; and then,
selecting as an operating level for the driving voltage, a level of the driving voltage for an iteration just prior to an iteration in which the operation fails.

2. The method of claim 1, wherein the varying the driving voltage comprises:
providing a test signal to the electronic device during each iteration of varying the driving voltage, and receiving a response signal from the electronic device in response to the test signal;
comparing the test signal to the response signal and generating a comparison result; and
determining on the basis of the comparison result whether the operation fails.

3. The method of claim 2, wherein the operation fails when the response signal varies from the test signal.

4. The method of claim 1, wherein the electronic device is a memory module and the operation is a read operation performed by the memory module.

5. The method of claim 1, wherein the electronic device is a memory module and the operation is a write operation performed by the memory module.

6. An electronic system comprising:
an electronic device; and
a control unit configured to iteratively vary the level of a driving voltage provided to the electronic device and perform an operation of the electronic device with each iteration until the operation fails, and then select as an operating level for the driving voltage, a level of the driving voltage for an iteration just prior to an iteration in which the operation fails.

7. The electronic system of claim 6, wherein the control unit is further configured to provide a test signal to the electronic device during each iteration of varying the driving voltage and receive a response signal from the electronic device in response to the test signal, compare the test signal to the response signal and generate a comparison result, and determine on the basis of the comparison result whether the operation fails.

8. The electronic system of claim 7, wherein the control unit comprises:
a logic circuit configured to sequentially provide a plurality of driving voltage codes according to an enable signal input by a user; and
a voltage regulator configured to provide a plurality of driving voltages that sequentially vary according to the plurality of driving voltage codes.

9. The electronic system of claim 8, wherein the logic circuit comprises:
a read/write (R/W) test unit configured to provide the test signal to the electronic device during each iteration of the plurality of driving voltages;
a comparison unit configured to compare the test signal and the response signal and generate the comparison results; and
a code storage unit configured to store the plurality of driving voltage codes and sequentially provide the plurality of driving voltage codes according to the comparison result.

10. The electronic system of claim 9, wherein the logic circuit stores one driving voltage code output from the voltage regulator for an iteration just prior to an iteration in which the operation fails.

11. The electronic system of claim 6, wherein the electronic system is a computer system, and the electronic device is a Single Inline Memory Module (SIMM) connected to the computer system.

12. The electronic system of claim 6, wherein the electronic system is a computer system, and the electronic device is a Double Inline Memory Module (DIMM) connected to the computer system.
